(19) United States
(12) Patent Application Publication
(10) Pub. No.: US 2007/0058467 A1
(43) Pub. Date: Mar. 15, 2007

(54) Semiconductor device, electro-optical device, and electronic instrument

(75) Inventor: Masahiko Tsuchiya, Suwa-shi (JP)

Correspondence Address: HARNESS, DICKEY & PIERCE, P.L.C., P.O. BOX 828, BLOOMFIELD HILLS, MI, 48303, US

(73) Assignee: Seiko Epson Corporation, Tokyo (JP)

(21) Appl. No.: 11/520,231

(22) Filed: Sep. 13, 2006

(30) Foreign Application Priority Data
Sep. 14, 2005 (JP) 2005-267600
Jun. 22, 2006 (JP) 2006-172233

(51) Int. Cl. G11C 7/00

(52) U.S. Cl. 365/205

(57) ABSTRACT

A semiconductor device includes first and second signal lines SL1 and SL2 through which signals with the same phase and the same amplitude are transmitted, and third and fourth signal lines SL3 and SL4 through which signals with different phases or different amplitudes are transmitted. The line-to-line distance when the first and second signal lines SL1 and SL2 are disposed in parallel is shorter than the line-to-line distance when the third and fourth signal lines SL3 and SL4 are disposed in parallel.

Japanese Patent Application No. 2005-267600 filed on Sep. 14, 2005, and Japanese Patent Application No. 2006-172233 filed on Jun. 22, 2006, are hereby incorporated by reference in their entirety.

### BACKGROUND OF THE INVENTION

The present invention relates to a semiconductor device, an electro-optical device, and an electronic instrument.

When driving an electro-optical device such as a liquid crystal display panel, it is necessary to generate various power supply voltages depending on the material and a drive method for an electro-optical element. The power supply voltages are generated by a power supply circuit. The power supply circuit generates the power supply voltages by increasing or decreasing a system power supply voltage.

The power supply circuit may include a charge-pump circuit which increases or decreases a voltage by a charge-pump operation. The charge-pump circuit can efficiently generate a voltage increased or decreased in the positive or negative direction at a low power consumption by the charge-pump operation using switch elements.

Such a charge-pump circuit is disclosed in JP-A-2000-330085 and JP-A-2000-333444, for example. JP-A-2000-330085 discloses a charge-pump circuit in which unnecessary self-current consumption accompanying charging/discharging a parasitic capacitor of each switch element is reduced by providing amplitude conversion means which converts an amplitude. JP-A-2000-333444 discloses a charge-pump circuit in which unnecessary self-current consumption accompanying charging/discharging a parasitic capacitor of a gate electrode of a transistor is reduced by short-circuiting gates of transistors forming switch elements.

However, the charge-pump circuits disclosed in JP-A-2000-330085 and JP-A-2000-333444 may decrease the boost efficiency when the arrangement of signal lines to which the increased or decreased voltage is supplied is not taken into consideration. Specifically, since it is necessary to charge/discharge a line-to-line capacitor between a signal line to which a voltage is supplied and a signal line adjacent thereto, self-power consumption is increased.

This problem is not limited to a signal line to which a voltage increased or decreased by the charge-pump circuit is supplied, but applies to all signal lines formed in a semiconductor device (integrated circuit (IC) in a narrow sense).

### SUMMARY

A first aspect of the invention relates to a semiconductor device comprising:

first and second signal lines through which signals with the same phase and the same amplitude are transmitted; and

third and fourth signal lines through which signals with different phases or different amplitudes are transmitted;

a line-to-line distance when the first and second signal lines are disposed in parallel being shorter than a line-to-line distance when the third and fourth signal lines are disposed in parallel.

A second aspect of the invention relates to a semiconductor device comprising:

first and second signal lines through which signals with the same phase and the same amplitude are transmitted; and

third and fourth signal lines through which signals with different phases or different amplitudes are transmitted;

the first and second signal lines being adjacently disposed in parallel; and

the third and fourth signal lines being disposed in parallel with at least one signal line provided between the third and fourth signal lines.

A third aspect of the invention relates to an electro-optical device comprising:

a plurality of scan lines;

a plurality of data lines;

a plurality of pixels;

a scan line driver circuit which scans the scan lines; and

the above semiconductor device which drives the data lines.

A fourth aspect of the invention relates to an electronic instrument comprising the above electro-optical device.

### BRIEF DESCRIPTION OF THE SEVERAL VIEWS OF THE DRAWING

FIG. 1 is a view illustrating an outline of a configuration of a semiconductor device according to one embodiment of the invention.

FIG. 2 is a view illustrative of signals with the same phase and the same amplitude according to one embodiment of the invention.

FIGS. 3A and 3B are views illustrative of the arrangement of signal lines for signals with the same phase and the same amplitude shown in FIG. 2.

FIG. 4 is a view illustrative of signals transmitted through first and second signal lines.

FIG. 5 is a view illustrative of signals with different phases or different amplitudes according to one embodiment of the invention.

FIGS. 6A to 6D are views illustrative of the arrangement of signal lines for the signals with different phases or different amplitudes shown in FIG. 5.

FIG. 7 is a view illustrative of signals transmitted through third and fourth signal lines.

FIG. 8 is a view illustrating an outline of a configuration of a semiconductor device according to one embodiment of the invention in which a charge-pump circuit is used as a power supply circuit.

FIG. 9 is a view illustrating an example of timings of charge clock signals and a control state of each transistor.

FIG. 10 is a view illustrating a waveform example of changes in voltages of signal lines shown in FIG. 8.

FIG. 11 is a view schematically illustrating a planar layout of a semiconductor device according to one embodiment of the invention.

FIG. 12 is a block diagram of a configuration example of a liquid crystal display device according to one embodiment of the invention.

FIG. 13 is a block diagram of another configuration example of a liquid crystal display device according to one embodiment of the invention.

FIG. 14 is a block diagram of a configuration example of a data line driver circuit shown in FIG. 12 or 13.

FIG. 15 is a block diagram of a configuration example of a scan line driver circuit shown in FIG. 12 or 13.

FIG. 16 is a block diagram of a configuration example of an electronic instrument according to one embodiment of the invention.

### DETAILED DESCRIPTION OF THE EMBODIMENT

The invention may provide a semiconductor device which reduces power consumption by reducing self-power consumption accompanying charging/discharging between signal lines, an electro-optical device, and an electronic instrument.

One embodiment of the invention relates to a semiconductor device comprising:

first and second signal lines through which signals with the same phase and the same amplitude are transmitted; and

third and fourth signal lines through which signals with different phases or different amplitudes are transmitted;

a line-to-line distance when the first and second signal lines are disposed in parallel being shorter than a line-to-line distance when the third and fourth signal lines are disposed in parallel.

According to this embodiment, a line-to-line capacitor is added to the first and second signal lines as a parasitic capacitor. Therefore, as the distance between the first and second signal lines becomes shorter, a change in the signal transmitted through one signal line affects a change in the signal transmitted through the other signal line to a larger extent due to the effects of capacitive coupling. According to this embodiment, since the signals transmitted through the first and second signal lines have the same phase and the same amplitude, the change direction of one signal coincides with the change direction of the other signal. Specifically, a change in one signal assists a change in the other signal due to capacitive coupling. This makes it unnecessary to additionally charge/discharge the line-to-line capacitor between the first and second signal lines, whereby self-power consumption can be reduced. As a result, power consumption can be reduced.

A line-to-line capacitor is also added to the third and fourth signal lines as a parasitic capacitor. On the other hand, since the signals transmitted through the third and fourth signal lines have different phases or different amplitudes, the change direction of one signal does not coincide with the change direction of the other signal. Specifically, a change in one signal interferes with a change in the other signal due to capacitive coupling. This makes it necessary to additionally charge/discharge the line-to-line capacitor between the third and fourth signal lines, whereby self-power consumption is increased.

According to this embodiment, unnecessary self-power consumption between the first and second signal lines can be reduced. Moreover, since the capacitance of the line-to-line capacitor between the third and fourth signal lines decreases, it becomes unnecessary to charge/discharge the line-to-line capacitor, whereby self-power consumption can be further reduced.

Another embodiment of the invention relates to a semiconductor device comprising:

first and second signal lines through which signals with the same phase and the same amplitude are transmitted; and

third and fourth signal lines through which signals with different phases or different amplitudes are transmitted;

the first and second signal lines being adjacently disposed in parallel; and

the third and fourth signal lines being disposed in parallel with at least one signal line provided between the third and fourth signal lines.

According to this embodiment, a line-to-line capacitor is added to the first and second signal lines as a parasitic capacitor. Therefore, as the distance between the first and second signal lines becomes shorter, a change in the signal transmitted through one signal line affects a change in the signal transmitted through the other signal line to a larger extent due to the effects of capacitive coupling. According to this embodiment, since the signals transmitted through the first and second signal lines have the same phase and the same amplitude, the change direction of one signal coincides with the change direction of the other signal. Specifically, a change in one signal assists a change in the other signal due to capacitive coupling. This makes it unnecessary to additionally charge/discharge the line-to-line capacitor between the first and second signal lines, whereby self-power consumption can be reduced. As a result, power consumption can be reduced.

On the other hand, since another signal line is provided between the third and the fourth signal lines, even if the signals transmitted through the third and fourth signal lines have different phases or different amplitudes, a situation can be prevented in which a change in one signal interferes with a change in the other signal due to capacitive coupling. This makes it unnecessary to additionally charge/discharge the line-to-line capacitor between the third and fourth signal lines, whereby an increase in self-power consumption can be prevented.

Therefore, this embodiment reduces unnecessary self-power consumption between the first and second signal lines, and prevents an increase in self-power consumption between the third and fourth signal lines.

In the semiconductor device according to this embodiment, the signals transmitted through the first and second signal lines may differ in voltage level.

In the semiconductor device according to this embodiment, the signals transmitted through the third and fourth signal lines may differ in voltage level.

The semiconductor device according to this embodiment may comprise:

a plurality of connection terminals each of which is connected with one end of a flying capacitor; and

a plurality of switch elements switch-controlled according to a charge-pump operation using the flying capacitors connected with the connection terminals;

wherein the first to fourth signal lines may be signal lines each of which electrically connects a connection node of the switch elements with the connection terminal.

In the semiconductor device according to this embodiment, voltages of the first and second signal lines may be supplied to both ends of one flying capacitor.

According to this embodiment, since the self-power consumption of the signal line to which the voltage increased by the charge-pump operation is supplied can be reduced, a semiconductor device can be provided which can increase the voltage at a reduced power consumption by suppressing a decrease in the boost efficiency.

In the semiconductor device according to this embodiment, the first and second signal lines may be adjacently disposed in a direction perpendicular to a wiring arrangement plane of the semiconductor device in which the first to fourth signal lines are disposed.

According to this embodiment, since the signal lines are disposed to overlap when viewed from above the wiring arrangement plane, the wiring region can be reduced even if the width of the signal line is increased in order to decrease the resistance of the signal line. Therefore, an inexpensive low-power-consumption semiconductor device can be provided which reduces the wiring region and suppresses an increase in self-power consumption.

The semiconductor device according to this embodiment may comprise a driver section which drives an electro-optical device based on a voltage of the connection node which outputs a voltage increased by the charge-pump operation among one or more connection nodes of the switch elements.

According to this embodiment, a semiconductor device can be provided which suppresses a decrease in the boost efficiency and drives an electro-optical device based on the voltage increased at reduced power consumption.

Another embodiment of the invention relates to an electro-optical device comprising:

a plurality of scan lines;

a plurality of data lines;

a plurality of pixels;

a scan line driver circuit which scans the scan lines; and

the above semiconductor device which drives the data lines.

According to this embodiment, an electro-optical device can be provided which includes a semiconductor device which reduces power consumption by reducing self-power consumption accompanying charging/discharging between signal lines. Specifically, an electro-optical device with reduced power consumption can be provided.

A further embodiment of the invention relates to an electronic instrument comprising the above electro-optical device.

According to this embodiment, an electronic instrument can be provided to which an electro-optical device including a semiconductor device, which reduces power consumption by reducing self-power consumption accompanying charging/discharging between signal lines, is applied. Specifically, an electronic instrument with reduced power consumption can be provided.

The embodiments of the invention are described below in detail with reference to the drawings. Note that the embodiments given below do not in any way limit the scope of the invention laid out in the claims. Note that all of the elements of the embodiments given below should not necessarily be taken as essential requirements for the invention.

1. Semiconductor device

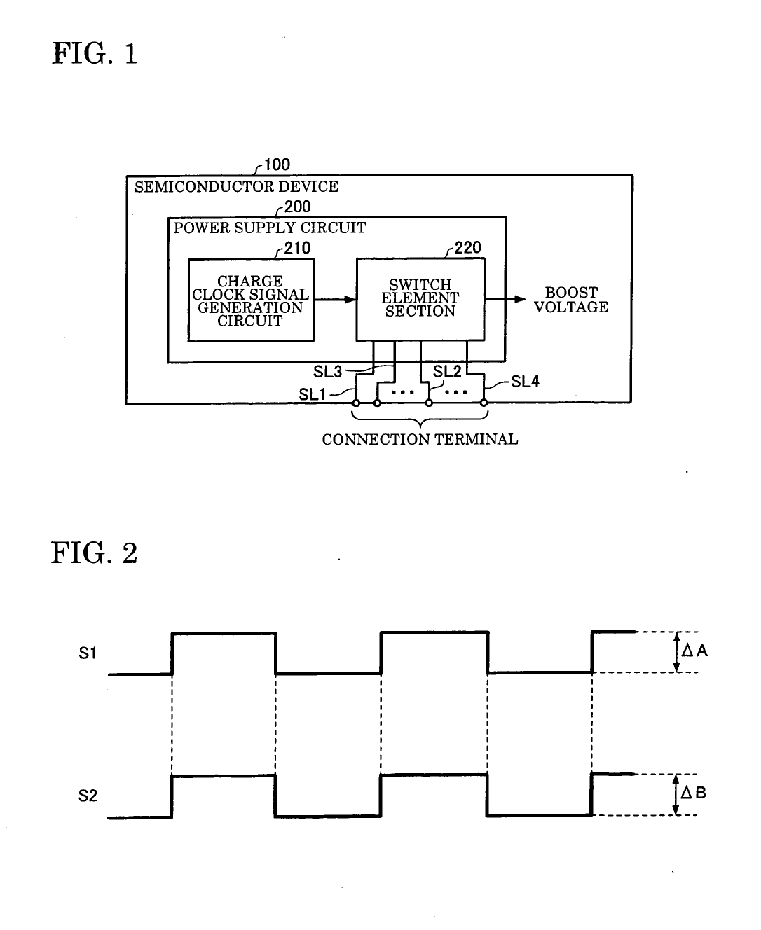

FIG. 1 illustrates an outline of a configuration of a semiconductor device according to this embodiment.

In FIG. 1, a semiconductor device 100 includes a power supply circuit 200. Note that the semiconductor device 100 may not include the power supply circuit 200. When the semiconductor device 100 includes the power supply circuit 200, the power supply circuit 200 generates a boost voltage obtained by increasing a given voltage by a charge-pump operation. The boost voltage is supplied to at least one element of the semiconductor device 100 so that a specific function is realized.

The power supply circuit 200 includes a charge clock signal generation circuit 210 and a switch element section 220. The charge clock signal generation circuit 210 generates one or more charge clock signals which serve as a reference timing of the charge-pump operation. The switch element section 220 includes a plurality of switch elements. Each switch element is switch-controlled (ON/OFF-controlled) using each charge clock signal.

The semiconductor device 100 includes a plurality of connection terminals. A flying capacitor which contributes to the charge-pump operation of the power supply circuit 200 is externally connected with the semiconductor device 100. One end of the flying capacitor is electrically connected with the connection terminal. The switch elements of the switch element section 220 are switch-controlled according to the charge-pump operation using the flying capacitors connected with the connection terminals.

The switch elements of the switch element section 220 and the connection terminals are electrically connected through a plurality of signal lines. For example, a connection node of the switch elements and the connection terminal are electrically connected through the signal line.

In regard to the arrangement of the signal lines which electrically connect the switch element section 220 and the connection terminals, it may be necessary to additionally charge/discharge the line-to-line capacitor between one signal line and a signal line adjacent thereto. This results in an increase in self-power consumption, whereby power consumption is increased. This embodiment provides a semiconductor device of which the power consumption is reduced by classifying signals into a signal group with the same phase and the same amplitude (e.g. first and second signal lines SL1 and SL2 in FIG. 1) and a signal group with different phases or different amplitudes (e.g. third and fourth signal lines SL3 and SL4 in FIG. 1), and arranging the signal lines suitably for each signal group.

FIG. 2 is a view illustrative of signals with the same phase and the same amplitude according to this embodiment.

Signals S1 and S2 transmitted through the first and second signal lines SL1 and SL2 of the signal lines from the switch element section 220 have the same phase and the same amplitude. Specifically, the amplitude (voltage) deltaA of the signal S1 transmitted through the first signal line SL1 is equal to the amplitude (voltage) deltaB of the signal S2 transmitted through the second signal line SL2. The rise timing (fall timing) of the signal S1 transmitted through the first signal line SL1 is (almost) the same as the rise timing (fall timing) of the signal S2 transmitted through the second signal line SL2. The signals S1 and S2 transmitted through the first and second signal lines SL1 and SL2 may differ in voltage level.

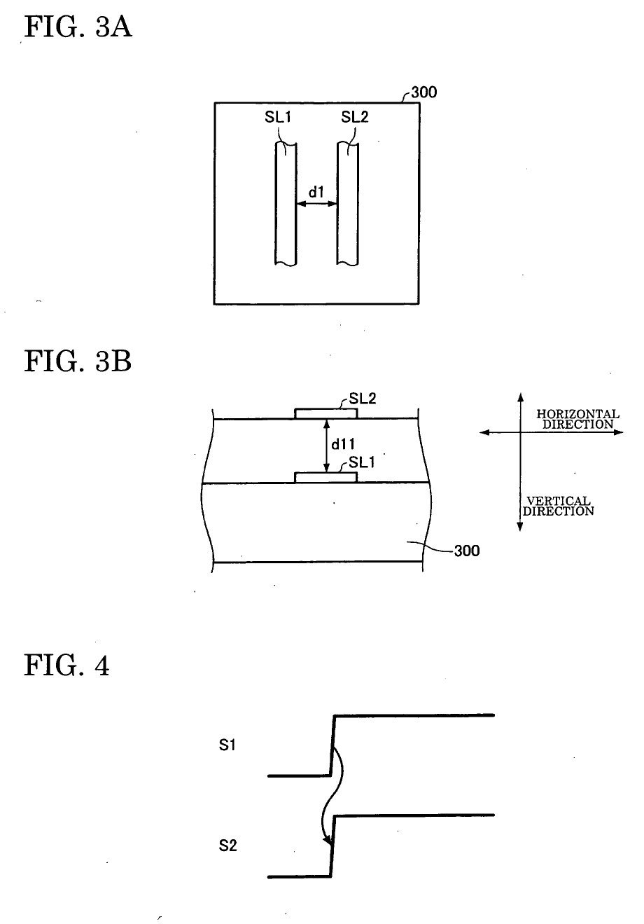

FIGS. 3A and 3B are views illustrative of the arrangement of the signal lines for the signals with the same phase and the same amplitude shown in FIG. 2. FIG. 3A is a schematic plan view of a wiring arrangement plane (principal plane of the semiconductor substrate) on which interconnects are disposed on a semiconductor substrate 300 on which the semiconductor device 100 is formed. FIG. 3B is a schematic cross-sectional view of the semiconductor substrate 300 in the direction perpendicular to the wiring arrangement plane.

As shown in FIG. 3A, the first and second signal lines SL1 and SL2 are adjacently disposed (or disposed so that the adjacent portion becomes as large as possible) in the horizontal direction on the wiring arrangement plane, for example. In this case, the first and second signal lines SL1 and SL2 are disposed so that the line-to-line distance when the first and second signal lines SL1 and SL2 are disposed in parallel is d1 (d1 is a positive number). The line-to-line distance (line-to-line pitch) used herein refers to the distance between the edges of two signal lines.

Or, as shown in FIG. 3B, the first and second signal lines SL1 and SL2 are adjacently disposed (or disposed so that the adjacent portion becomes as large as possible) through an insulating layer in the direction perpendicular to the wiring arrangement plane, for example. Specifically, the first and second signal lines SL1 and SL2 are disposed so that the first and second signal lines SL1 and SL2 at least partially overlap when viewed from the top side of the semiconductor substrate 300. In this case, the first and second signal lines SL1 and SL2 are disposed so that the line-to-line distance when the first and second signal lines SL1 and SL2 are disposed in parallel is d11 (d11 is a positive number).

FIG. 4 is a view illustrative of the signals transmitted through the first and second signal lines SL1 and SL2.

When adjacently disposing the first and second signal lines SL1 and SL2 in the horizontal direction or the vertical direction as shown in FIG. 3A or 3B, a line-to-line capacitor is added to the first and second signal lines SL1 and SL2 as a parasitic capacitor. Therefore, as the distance d1 or d11 becomes shorter, a change in the signal transmitted through one signal line affects a change in the signal transmitted through the other signal line to a larger extent due to the effects of capacitive coupling.

On the other hand, when the signals have the same phase and the same amplitude such as the signals S1 and S2, the change direction of the signal S1 coincides with the change direction of the signal S2, as shown in FIG. 4, whereby the change in the signal S1 assists the change in the signal S2. This makes it unnecessary to additionally charge/discharge the line-to-line capacitor between the first and second signal lines SL1 and SL2, whereby self-power consumption is reduced. As a result, power consumption can be reduced.

A shield line may be disposed between the signal lines. However, this causes a line-to-line capacitor to be added between each signal line and the shield line as a parasitic capacitor, whereby self-power consumption increases accompanying charging/discharging the parasitic capacitor. In this embodiment, since the parasitic capacitor functions so that a change in one signal assists a change in the other signal, as described above, an increase in self-power consumption accompanying charging/discharging the parasitic capacitor can be reduced.

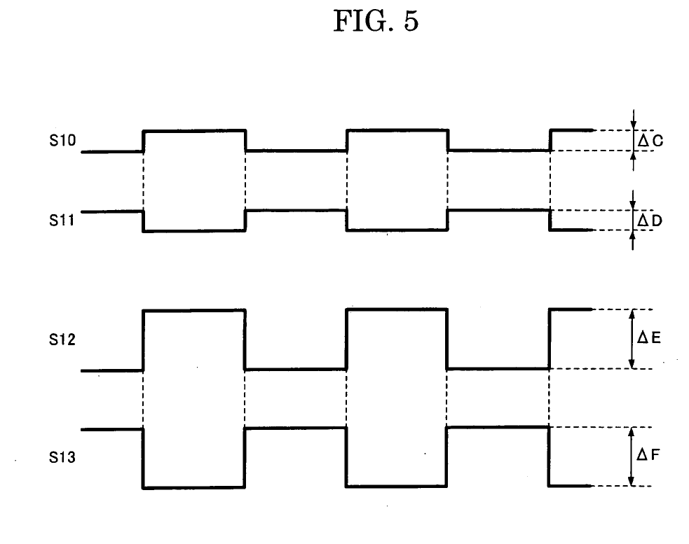

FIG. 5 is a view illustrative of signals with different phases or different amplitudes according to this embodiment.

Signals S10, S11, S12, and S13 transmitted through four signal lines of the signal lines from the switch element section 220 have different phases or different amplitudes, for example. In FIG. 5, the amplitude (voltage) deltaC of the signal S10 is equal to the amplitude (voltage) deltaD of the signal S11, and the amplitude (voltage) deltaE of the signal S12 is equal to the amplitude (voltage) deltaF of the signal S13.

In FIG. 5, the signals S10 and S11 have the same amplitude but differ in phase. The signals S10 and S12 differ in amplitude but have the same phase. Likewise, the signals S10 and S13 differ in amplitude and phase.

The signals S11 and S12 differ in amplitude and phase. Likewise, the signals S11 and S13 differ in amplitude but have the same phase. The signals S12 and S13 have the same amplitude but differ in phase.

Specifically, the signals S11 to S13 shown in FIG. 5 do not have the same phase and the same amplitude, but have different phases or different amplitudes. Therefore, when the signal lines through which two of the signals S11 to S13 are transmitted are the third and fourth signal lines SL3 and SL4 from the switch element section 220, the signals transmitted through the third and fourth signal lines SL3 and SL4 are signals with different phases or different amplitudes. The signals transmitted through the third and fourth signal lines SL3 and SL4 may differ in voltage level.

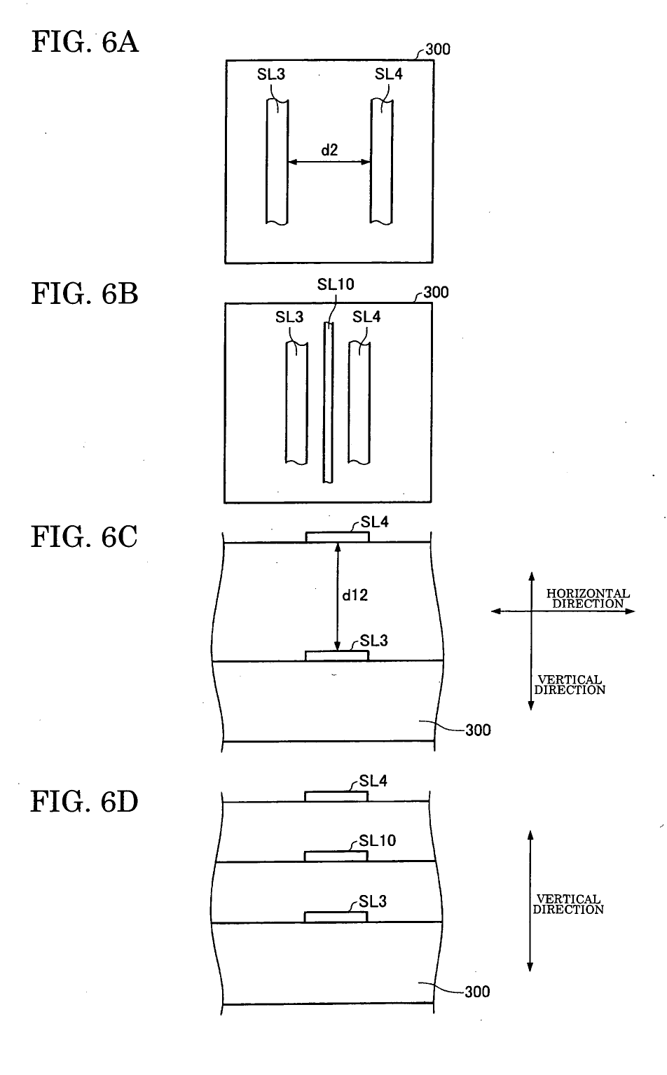

FIGS. 6A to 6D are views illustrative of the arrangement of the signal lines for the signals with different phases or different amplitudes shown in FIG. 5. FIGS. 6A and 6B are schematic plan views of the wiring arrangement plane (principal plane of the semiconductor substrate) on which interconnects are disposed on the semiconductor substrate 300 on which the semiconductor device 100 is formed. FIGS. 6C and 6D are schematic cross-sectional views of the semiconductor substrate 300 in the direction perpendicular to the wiring arrangement plane.

As shown in FIG. 6A, when disposing the third and fourth signal lines SL3 and SL4 in the horizontal direction on the wiring arrangement plane, the third and fourth signal lines SL3 and SL4 are disposed so that the line-to-line distance becomes as large as possible (so that the line-to-line pitch becomes as large as possible), for example. In more detail, when the line-to-line distance when the third and fourth signal lines SL3 and SL4 are disposed in parallel is d2 (d2 is a positive number), the third and fourth signal lines SL3 and SL4 are disposed so that the line-to-line distance d2 is greater than the line-to-line distance d1. The line-to-line distance used herein refers to the distance between the edges of two signal lines.

Or, as shown in FIG. 6B, the third and fourth signal lines SL3 and SL4 may be disposed in parallel in a state in which at least one signal line SL10 is provided between the third and fourth signal lines SL3 and SL4. The signal line SL10 may be a shield line set at a specific voltage level. In this case, since another signal line is provided between the third and fourth signal lines SL3 and SL4, even if the signals transmitted through the third and fourth signal lines SL3 and SL4 have different phases or different amplitudes, a situation can be prevented in which a change in one signal interferes with a change in the other signal due to capacitive coupling. This makes it unnecessary to additionally charge/discharge the line-to-line capacitor between the third and fourth signal lines SL3 and SL4, whereby an increase in self-power consumption can be prevented.

Or, as shown in FIG. 6C, when adjacently disposing the third and fourth signal lines SL3 and SL4 through an insulating layer in the direction perpendicular to the wiring arrangement plane, the third and fourth signal lines SL3 and SL4 are disposed so that the line-to-line distance becomes as large as possible, for example. In more detail, the third and fourth signal lines SL3 and SL4 are disposed so that the third and fourth signal lines SL3 and SL4 at least partially overlap when viewed from the top side of the semiconductor substrate 300. In this case, when the line-to-line distance when the third and fourth signal lines SL3 and SL4 are disposed to overlap in the vertical direction is d12 (d12 is a positive number), the third and fourth signal lines SL3 and SL4 are disposed so that the line-to-line distance dl2 is greater than the line-to-line distance d11. Or, as shown in FIG. 6D, the third and fourth signal lines SL3 and SL4 may be disposed to overlap in the vertical direction through an insulating layer so that at least one signal line SL10 is provided between the third and fourth signal lines SL3 and SL4. The signal line SL10 may be a shield line set at a specific voltage level.

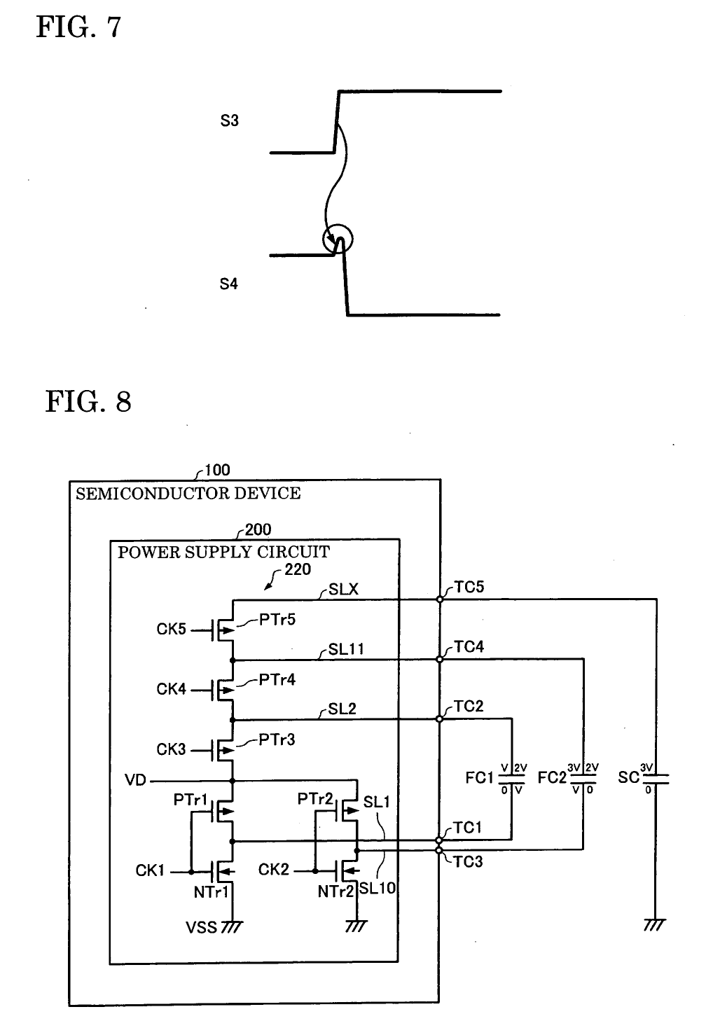

FIG. 7 is a view illustrative of the signals transmitted through the third and fourth signal lines SL3 and SL4.

In general, when adjacently disposing the third and fourth signal lines SL3 and SL4 in the horizontal direction or the vertical direction, a line-to-line capacitor is added to the third and fourth signal lines SL3 and SL4 as a parasitic capacitor. Therefore, as the distance d2 or d12 shown in FIGS. 6A to 6D becomes shorter, a change in the signal transmitted through one signal line affects a change in the signal transmitted through the other signal line to a larger extent due to the effects of capacitive coupling. Therefore, when the signals have different phases or different amplitudes such as the signals S3 and S4, the change direction of the signal S3 does not coincide with the change direction of the signal S4, as shown in FIG. 7, whereby the change in the signal S3 interferes with the change in the signal S4. This makes it necessary to additionally charge/discharge the line-to-line capacitor between the third and fourth signal lines SL3 and SL4, whereby self-power consumption increases.

Therefore, since the capacitance of the line-to-line capacitor between the third and fourth signal lines SL3 and SL4 decreases as the distance d2 or d12 increases, it becomes unnecessary to additionally charge/discharge the line-to-line capacitor, whereby self-power consumption can be reduced.

In this embodiment, when the semiconductor device includes the first and second signal lines SL1 and SL2, through which the signals with the same phase and the same amplitude are transmitted, and the third and fourth signal lines SL3 and SL4, through which the signals with different phases or different amplitudes are transmitted, the line-to-line distance d1 when the first and second signal lines SL1 and SL2 are disposed in parallel is set to be smaller than the line-to-line distance d2 when the third and fourth signal lines SL3 and SL4 are disposed in parallel. This reduces unnecessary self-power consumption between the first and second signal lines SL1 and SL2, and prevents an increase in self-power consumption between the third and fourth signal lines SL3 and SL4.

2. Power supply circuit

A case of using a charge-pump circuit as the power supply circuit 200 included in the semiconductor device 100 according to this embodiment is described below.

FIG. 8 illustrates an outline of a configuration of the semiconductor device 100 according to this embodiment in which a charge-pump circuit is used as the power supply circuit. In FIG. 8, the same sections as in FIG. 1 are indicated by the same symbols. Description of these sections is appropriately omitted. In FIG. 8, the charge-pump circuit performs a threefold boost operation. Note that this embodiment is not limited to the boost factor.

FIG. 8 illustrates only a configuration example of the switch element section 220 as the power supply circuit 200. Transistors (switch elements) included in the switch element section 220 are switch-controlled using charge clock signals CK1 to CK5 generated by the charge clock signal generation circuit 210 (not shown).

The switch element section 220 of the power supply circuit 200 includes a P-type (first conductivity type) metal-oxide-semiconductor (MOS) transistor (MOS transistor is hereinafter abbreviated as “transistor”) PTr1 of which the source is connected with a system power supply VD, and an N-type (second conductivity type) transistor NTr1 of which the drain is connected with the drain of the transistor PTr1. The source of the transistor NTr1 is connected with a system ground power supply VSS. The charge clock signal CK1 is supplied to the gates of the transistors PTr1 and NTr1.

The switch element section 220 includes a P-type transistor PTr2 of which the source is connected with the system power supply VD, and an N-type transistor NTr2 of which the drain is connected with the drain of the transistor PTr2. The source of the transistor NTr2 is connected with the system ground power supply VSS. The charge clock signal CK2 is supplied to the gates of the transistors PTr2 and NTr2.

The switch element section 220 further includes P-type transistors PTr3, PTr4, and PTr5. The drain of the transistor PTr3 is connected with the system power supply VD, and the source of the transistor PTr3 is connected with the drain of the P-type transistor PTr4. The source of the transistor PTr3 is connected with the drain of the P-type transistor PTr5. The source of the transistor PTr5 is connected with a connection terminal TC5 of the semiconductor device 100 through an output signal line SLX. The charge clock signal CK3 is supplied to the gate of the transistor PTr3. The charge clock signal CK4 is supplied to the gate of the transistor PTr4. The charge clock signal CK5 is supplied to the gate of the transistor PTr5.

The semiconductor device 100 further includes connection terminals TC1 to TC4. The connection terminal TC1 and the connection node (drain node) of the transistors PTr1 and NTr1 are electrically connected through the signal line SL1 (first signal line SL1). The connection terminal TC2 and the connection node (drain node) of the transistors PTr3 and NTr4 are electrically connected through the signal line SL2 (second signal line SL2). The connection terminal TC3 and the connection node of the transistors PTr2 and NTr2 are electrically connected through the signal line SL10. The connection terminal TC4 and the connection node of the transistors PTr4 and PTr5 are electrically connected through the signal line SL11.

A flying capacitor FC1 is connected between the connection terminals TC1 and TC2 outside the semiconductor device 100. A flying capacitor FC2 is connected between the connection terminals TC3 and TC4 outside the semiconductor device 100. A stabilization capacitor SC is connected between the connection terminal TC5 and the system ground power supply VSS.

The power supply circuit 200 shown in FIG. 8 outputs to the connection terminal TC5 a boost voltage of 3 V obtained by increasing the voltage V between the system power supply voltage VD and the system ground power supply voltage VSS three times.

As described above, the semiconductor device 100 may include a plurality of connection terminals each of which is connected with one end of a flying capacitor, and a plurality of switch elements switch-controlled according to a charge-pump operation using the flying capacitors connected with the connection terminals. The signal line in FIG. 8 may be referred to as a signal line which electrically connects a connection node of the switch elements with the connection terminal.

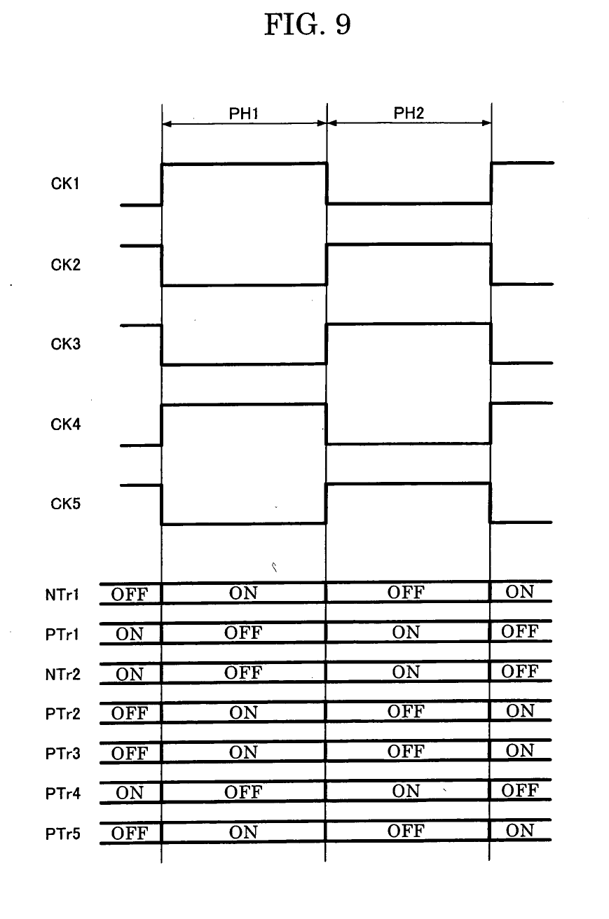

FIG. 9 illustrates an example of the timings of the charge clock signals CK1 to CK5 and the control state of each transistor. In FIG. 9, the rising edge and the falling edge of each charge clock signal occur at the same timing. It is preferable to cause the rising edge and the falling edge of each charge clock signal to occur at different timings so that two transistors connected in series are not simultaneously turned ON (so that an OFF-OFF period is provided).

In a period PH1, the transistor NTr1 is turned ON and the transistor PTr1 is turned OFF, whereby one end of the flying capacitor FC1 connected with the connection terminal TC1 is connected with the system ground power supply VSS. In this case, since the transistor PTr3 is turned ON and the transistor PTr4 is turned OFF, the other end of the flying capacitor FC1 connected with the connection terminal TC2 is connected with the system power supply VD through the signal line SL2. Therefore, the flying capacitor FC1 stores charges corresponding to the voltage V between the system power supply VD and the system ground power supply VSS in the period PH1.

In a period PH2, the transistor NTr1 is turned OFF and the transistor PTr1 is turned ON, whereby one end of the flying capacitor FC1 connected with the connection terminal TC1 is connected with the system power supply VD. Therefore, the voltage of the other end of the flying capacitor FC2 connected with the connection terminal TC2 is set at 2 V. Since the transistor PTr3 is turned OFF and the transistor PTr4 is turned ON, 2 V is supplied to one end of the flying capacitor FC2 connected with the connection terminal TC4. In this case, since the transistor NTr2 is turned ON and the transistor PTr2 is turned OFF, the other end of the flying capacitor FC2 connected with the connection terminal TC3 is connected with the system ground power supply VSS through the signal line SL10.

In the period PH1 subsequent to the period PH2, the transistor NTr2 is turned OFF and the transistor PTr2 is turned ON, whereby the other end of the flying capacitor FC2 connected with the connection terminal TC3 is connected with the system power supply VD. This causes one end of the flying capacitor FC2 connected with the connection terminal TC4 to be set at 3 V through the signal line SL11. In this case, since the transistor PTr5 is turned ON, 3 V is supplied to one end of the stabilization capacitor SC through the output signal line SLX. This voltage is then held by the stabilization capacitor SC.

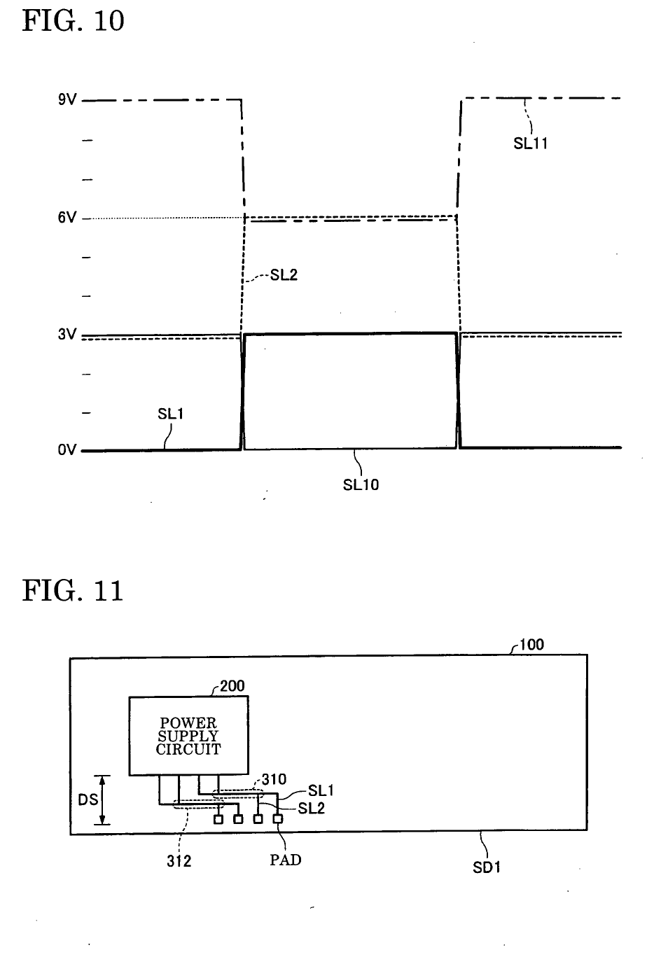

FIG. 10 illustrates a waveform example of changes in voltages of the signal lines SL1, SL2, SL10, and SL11 shown in FIG. 8. In FIG. 10, the voltage of the system ground power supply VSS is 0 V, and the voltage of the system power supply VD is 3 V.

The signals transmitted through the signal lines SL1 and SL2 are signals with the same phase and the same amplitude. The signals transmitted through the signal lines SL10 and SL11 are also signals with the same phase and the same amplitude. Therefore, the signals with the same phase and the same amplitude transmitted through the signal lines SL1 and SL2 are supplied to either end of the flying capacitor FC1. The signals with the same phase and the same amplitude transmitted through the signal lines SL10 and SL11 are supplied to either end of the flying capacitor FC2.

Therefore, the signal lines SL1 and SL2 are adjacently disposed at the line-to-line distance d1, and the signal lines SL10 and SL11 are adjacently disposed at the line-to-line distance d1. Since the signals transmitted through the signal lines SL1 and SL10 or the signals transmitted through the signal lines SL2 and SL11 have different phases or different amplitudes, the signal lines SL1 and SL10 or the signal lines SL2 and SL11 are disposed at the line-to-line distance d2, for example. This reduces self-power consumption accompanying charging/discharging the line-to-line capacitor.

FIG. 11 schematically illustrates a layout plan view of the semiconductor device 100 according to this embodiment.

When the semiconductor device 100 is provided in a rectangular region, as shown in FIG. 11, pads (connection terminals) are disposed along the edge of a side SD1 of the semiconductor device 100 extending in the long side direction, for example. In this case, it is necessary to reduce a length DS in the short side direction of the semiconductor device 100 by appropriately creating an arrangement of the signal lines connecting the power supply circuit 200 and the pads.

When the semiconductor device includes the first and second signal lines SL1 and SL2 through which the signals with the same phase and the same amplitude are transmitted and the third and fourth signal lines SL3 and SL4 through which the signals with different phases or different amplitudes are transmitted, the first and second signal lines are adjacently disposed in the direction perpendicular to the wiring arrangement plane of the semiconductor device 100 (see FIG. 3B). In this case, the line-to-line distance is set at d1. This allows the signal lines to be disposed to overlap when viewed from the above the wiring arrangement plane, as indicated by the broken lines 310 and 312 in FIG. 11, whereby the length DS can be reduced.

When generating the boost voltage by the charge-pump operation such as in the power supply circuit 200, it is indispensable to increase the size of the transistor (switch element) and reduce the resistance of the signal line in order not to decrease the boost efficiency. Therefore, it is necessary to increase the width of the signal line. Accordingly, the wiring region can be reduced by disposing the signal lines to overlap, as shown in FIG. 11. Moreover, power consumption can be reduced by suppressing an increase in self-power consumption, as shown in FIG. 4.

It is preferable to dispose the third and fourth signal lines at the line-to-line distance d2 in the direction perpendicular to the wiring arrangement plane, as shown in FIG. 6C, or dispose the third and fourth signal lines with another signal line interposed therebetween, as shown in FIG. 6D. In this case, self-power consumption can be reduced.

The above-described semiconductor device according to this embodiment may be applied to a driver circuit which drives an electro-optical device.

3. Liquid crystal display device

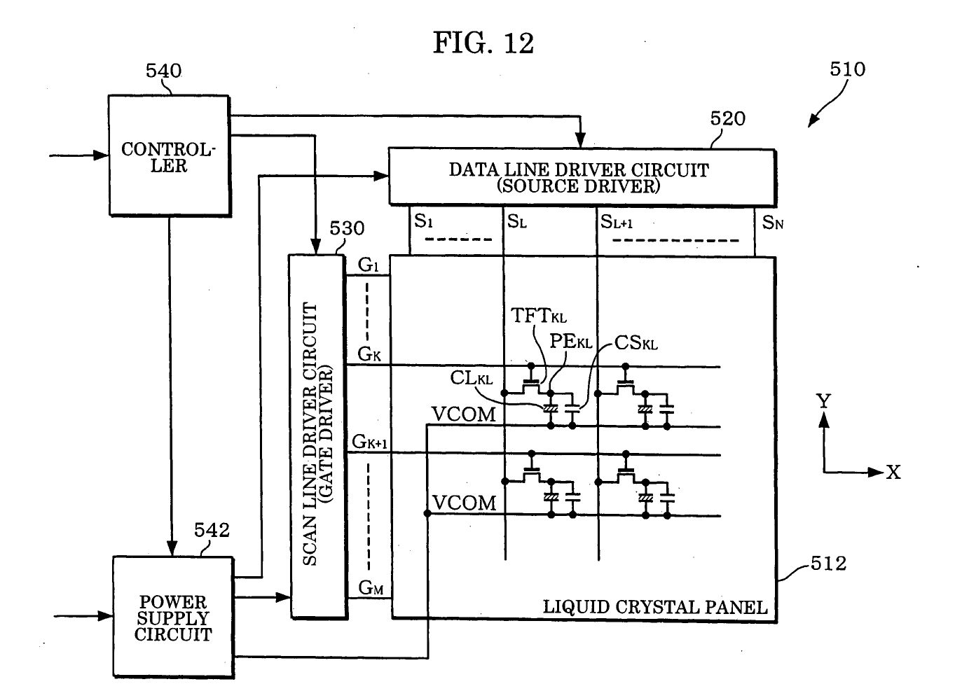

FIG. 12 is a block diagram of a configuration example of a liquid crystal display device according to this embodiment.

A liquid crystal display device 510 (display device in a broad sense) includes a liquid crystal panel 512 (display panel in a broad sense; electro-optical device in a broader sense), a data line driver circuit 520 (source driver in a narrow sense), a scan line driver circuit 530 (gate driver in a narrow sense), a controller 540, and a power supply circuit 542. The liquid crystal display device 510 need not necessarily include all of these circuit blocks. The liquid crystal display device 510 may have a configuration in which some of these circuit blocks are omitted.

The liquid crystal panel 512 includes a plurality of scan lines (gate lines in a narrow sense), a plurality of data lines (source lines in a narrow sense), and pixel electrodes specified by the scan lines and the data lines. In this case, an active matrix type liquid crystal display device may be formed by connecting a thin film transistor TFT (switching element in a broad sense) with the data line and connecting the pixel electrode with the thin film transistor TFT.

In more detail, the liquid crystal panel 512 is formed on an active matrix substrate (e.g. glass substrate). A plurality of scan lines G₁ to G_{M} (M is a positive integer of two or more), arranged in a direction Y in FIG. 12 and extending in a direction X, and a plurality of data lines S₁ to S_{N} (N is a positive integer of two or more), arranged in the direction X and extending in the direction Y, are disposed on the active matrix substrate. The thin film transistor TFT_{KL} (switching element in a broad sense) is provided at a position corresponding to the intersection point of the scan line G_{K} (1≦K≦M, K is a positive integer) and the data line S_{L} (1≦L≦N, L is a positive integer).

A gate electrode of the thin film transistor TFT_{KL} is connected with the scan line G_{K}, a source electrode of the thin film transistor TFT_{KL} is connected with the data line S_{L}, and a drain electrode of the thin film transistor TFT_{KL} is connected with a pixel electrode PE_{KL}. A liquid crystal capacitor CL_{KL} (liquid crystal element) and a storage capacitor CS_{KL} are formed between the pixel electrode PE_{KL} and a common electrode VCOM opposite to the pixel electrode PE_{KL} through a liquid crystal element (electro-optical material in a broad sense). A liquid crystal is sealed between the active matrix substrate, on which the thin film transistor TFT_{KL}, the pixel electrode PE_{KL}, and the like are formed, and a common substrate on which the common electrode VCOM is formed. The transmissivity of the pixel changes depending on the voltage applied between the pixel electrode PE_{KL} and the common electrode VCOM.

A voltage applied to the common electrode VCOM is generated by the power supply circuit 542. The common electrode VCOM may be formed in a stripe pattern corresponding to each scan line instead of forming the common electrode VCOM over the entire common substrate.

The data line driver circuit 520 drives the data lines S₁ to S_{N} of the liquid crystal panel 512 based on grayscale data. The scan line driver circuit 530 sequentially scans the scan lines G₁ to G_{M} of the liquid crystal panel 512.

The controller 540 controls the data line driver circuit 520, the scan line driver circuit 530, and the power supply circuit 542 according to information set by a host (not shown) such as a central processing unit (CPU).

In more detail, the controller 540 sets an operation mode or supplies a vertical synchronization signal or a horizontal synchronization signal generated therein to the data line driver circuit 520 and the scan line driver circuit 530, and controls the polarity reversal timing of the voltage of the common electrode VCOM for the power supply circuit 542, for example.

The power supply circuit 542 generates various voltages (grayscale voltage) necessary for driving the liquid crystal panel 512 and the voltage applied to the common electrode VCOM based on a reference voltage supplied from the outside. The power supply circuit 542 has the function of the power supply circuit 200 shown in FIG. 1 or 8. Accordingly, a flying capacitor and a stabilization capacitor (not shown) are externally connected with the data line driver circuit 520, and the power supply circuit 542 generates the voltages such as the grayscale voltage by a charge-pump operation.

In FIG. 12, the liquid crystal display device 510 includes the controller 540. Note that the controller 540 may be provided outside the liquid crystal display device 510. The host may be provided in the liquid crystal display device 510 together with the controller 540.

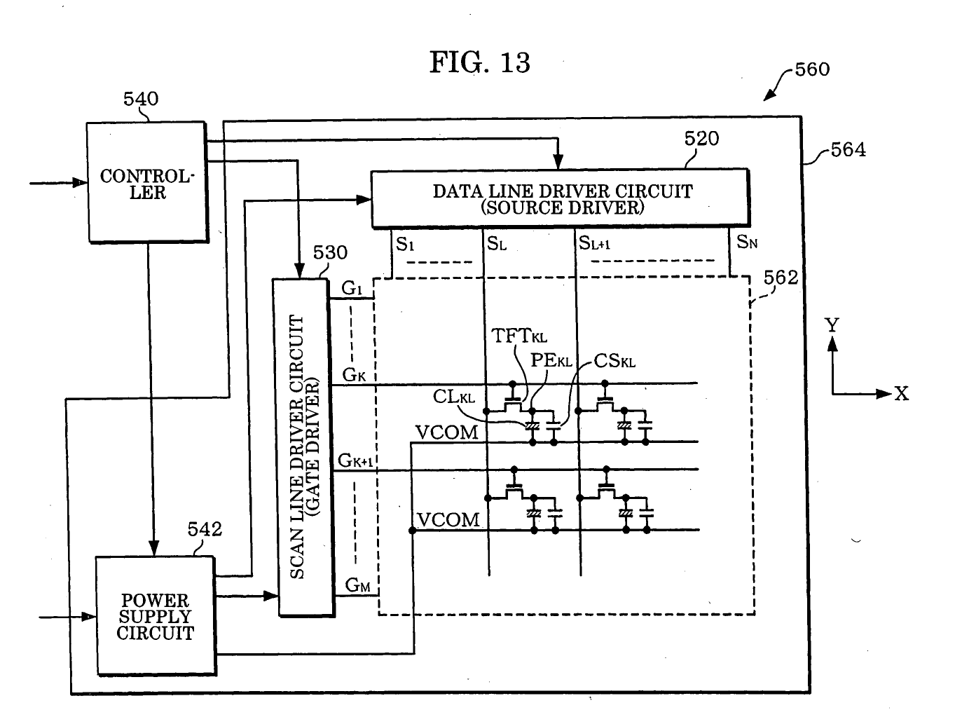

FIG. 13 is a block diagram of another configuration example of the liquid crystal display device according to this embodiment. In FIG. 13, the same sections as in FIG. 12 are indicated by the same symbols. Description of these sections is appropriately omitted.

In a liquid crystal device 560 shown in FIG. 13, the data line driver circuit 520, the scan line driver circuit 530, and the power supply circuit 542 are formed on an active matrix substrate 564 in which pixels are formed in a pixel formation region 562 as described above. At least one of the data line driver circuit 520, the scan line driver circuit 530, and the power supply circuit 542 shown in FIG. 13 may be omitted from the circuit blocks formed on the active matrix substrate 564. The controller 540 may be additionally formed on the active matrix substrate 564 shown in FIG. 13.

3.1 Data line driver circuit

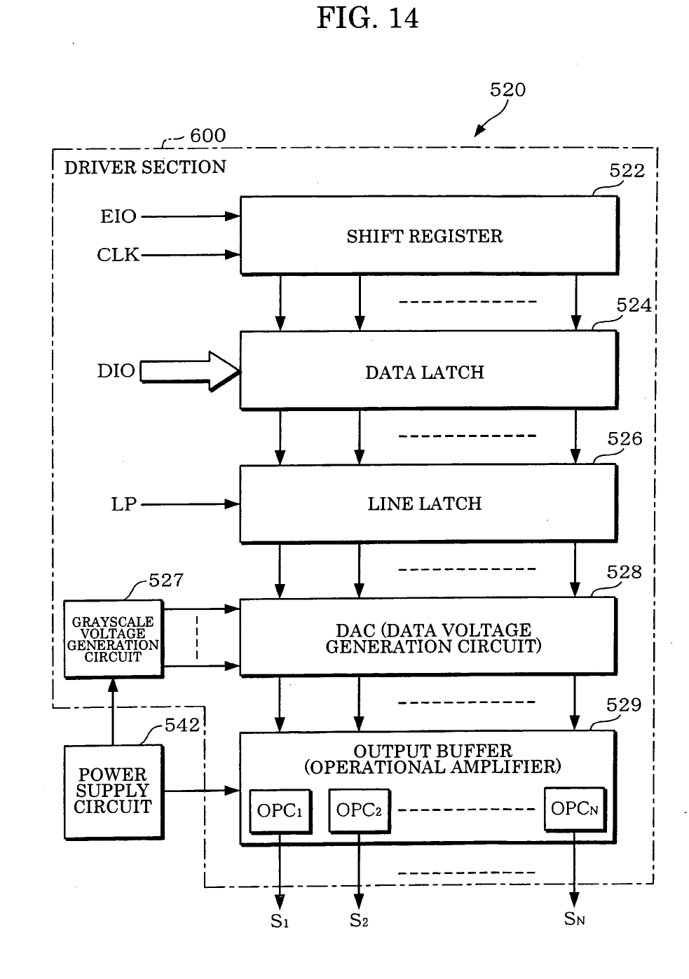

FIG. 14 illustrates a configuration example of the data line driver circuit 520 shown in FIG. 12 or 13. FIG. 14 illustrates a configuration example when the power supply circuit 542 is provided in the data line driver circuit 520. Specifically, an example in which the semiconductor device according to this embodiment is applied to the data line driver circuit 520 is illustrated in FIG. 14.

The data line driver circuit 520 (driver circuit in a broad sense) includes a driver section 600 and the power supply circuit 542. The driver section 600 includes a shift register 522, a data latch 524, a line latch 526, a DAC 528 (digital-analog conversion circuit; data voltage generation circuit in a broad sense), and an output buffer 529 (operational amplifier).

The shift register 522 includes a plurality of flip-flops provided in data line units and sequentially connected. The shift register 522 holds an enable input-output signal EIO in synchronization with a clock signal CLK, and sequentially shifts the enable input-output signal EIO to the adjacent flip-flops in synchronization with the clock signal CLK.

Grayscale data (DIO) is input to the data latch 524 from the controller 540 in units of 18 bits (6 bits (grayscale data)×3 (each color of RGB)), for example. The data latch 524 latches the grayscale data (DIO) in synchronization with the enable input-output signal EIO sequentially shifted by the flip-flops of the shift register 522.

The line latch 526 latches the grayscale data in horizontal scan units latched by the data latch 524 in synchronization with a horizontal synchronization signal LP supplied from the controller 540.

A grayscale voltage generation circuit 527 divides the power supply voltage from the power supply circuit 542 using resistors to generate a plurality of grayscale voltages. The grayscale voltages generated by the grayscale voltage generation circuit 527 are supplied to the DAC 528.

The DAC 528 generates an analog data voltage supplied to each data line. In more detail, the DAC 528 selects one of the grayscale voltages from the grayscale voltage generation circuit 527 based on the digital grayscale data from the line latch 526, and outputs an analog data voltage corresponding to the digital grayscale data.

The output buffer 529 buffers the data voltage from the DAC 528, and drives the data line by outputting the data voltage to the data line. In more detail, the output buffer 529 includes voltage-follower-connected operational amplifiers OPC₁ to OPC_{N} provided in data line units. The operational amplifier subjects the data voltage from the DAC 528 to impedance conversion, and outputs the resulting voltage to each data line.

Therefore, the driver section 600 drives the electro-optical device based on the voltage of the connection node which outputs the voltage increased by the charge-pump operation among one or more connection nodes of the switch elements of the switch element section 220 of the power supply circuit 200 shown in FIG. 8.

In FIG. 14, the digital grayscale data is subjected to digital-analog conversion and output to the data line through the output buffer 529. Note that an analog image signal may be sampled/held and output to the data line through the output buffer 529.

3.2 Scan line driver circuit

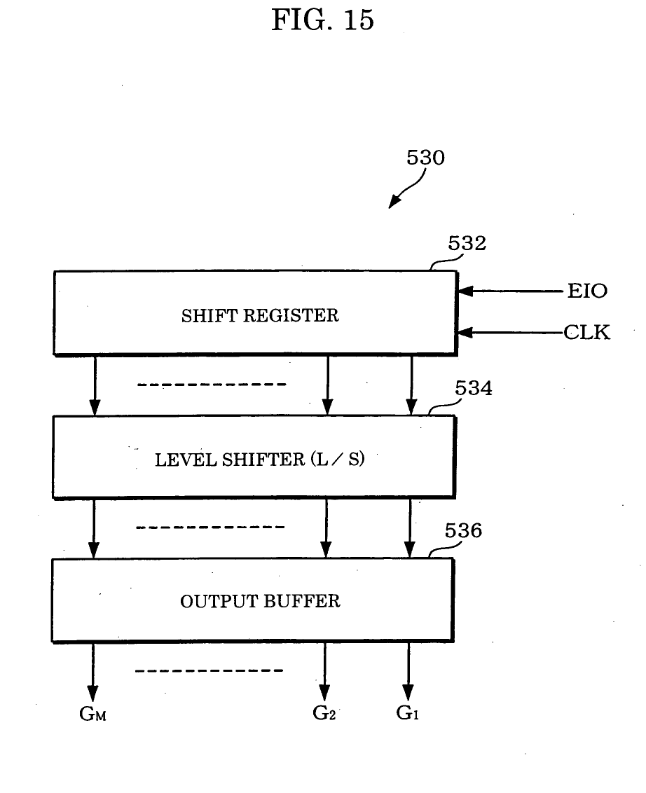

FIG. 15 illustrates a configuration example of the scan line driver circuit 530 shown in FIG. 12 or 13.

The scan line driver circuit 530 includes a shift register 532, a level shifter 534, and an output buffer 536.

The shift register 532 includes a plurality of flip-flops provided in scan line units and sequentially connected. The shift register 532 holds the enable input-output signal EIO in the flip-flop in synchronization with the clock signal CLK, and sequentially shifts the enable input-output signal EIO to the adjacent flip-flops in synchronization with the clock signal CLK. The enable input-output signal EIO input to the shift register 532 is a vertical synchronization signal supplied from the controller 540.

The level shifter 534 shifts the level of the voltage from the shift register 532 to the voltage level corresponding to the liquid crystal element of the liquid crystal panel 512 and the transistor performance of the thin film transistor TFT. As the voltage level, a high voltage level of 20 to 50 V is necessary, for example.

The output buffer 536 buffers the scan voltage shifted by the level shifter 534, and drives the scan line by outputting the scan voltage to the scan line.

4. Electronic instrument

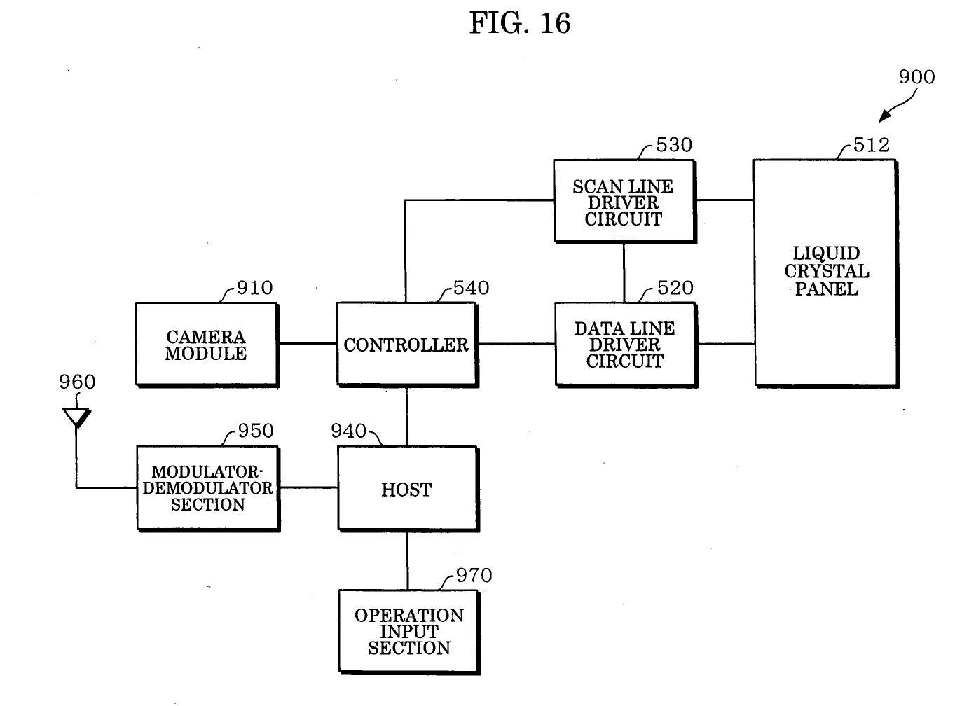

FIG. 16 is a block diagram of a configuration example of an electronic instrument according to this embodiment. FIG. 16 illustrates a configuration example of a portable telephone as an example of the electronic instrument. In FIG. 16, the same sections as in FIG. 12 or 13 are indicated by the same symbols. Description of these sections is appropriately omitted.

A portable telephone 900 includes a camera module 910. The camera module 910 includes a CCD camera, and supplies grayscale data of an image captured using the CCD camera to the controller 540 in a YUV format.

The portable telephone 900 includes the liquid crystal panel 512. The liquid crystal panel 512 (electro-optical device in a broad sense) is driven by the data line driver circuit 520 and the scan line driver circuit 530. The liquid crystal panel 512 includes scan lines, data lines, and pixels. The data line driver circuit 520 includes the power supply circuit 542, as shown in FIG. 14. The power supply circuit 542 (not shown) of the data line driver circuit 520 is connected with the data line driver circuit 520 and the scan line driver circuit 530, and supplies the drive power supply voltage to each driver circuit. The power supply circuit 542 supplies a common electrode voltage Vcom to the common electrode of the liquid crystal panel 512.

The controller 540 is connected with the data line driver circuit 520 and the scan line driver circuit 530, and supplies grayscale data in an RGB format to the data line driver circuit 520.

A host 940 is connected with the controller 540. The host 940 controls the controller 540. The host 940 demodulates grayscale data received through an antenna 960 using a modulator-demodulator section 950, and supplies the demodulated grayscale data to the controller 540. The controller 540 causes the data line driver circuit 520 and the scan line driver circuit 530 to display an image on the liquid crystal panel 512 based on the grayscale data.

The host 940 modulates grayscale data generated by the camera module 910 using the modulator-demodulator section 950, and directs transmission of the modulated data to another communication device through the antenna 960.

The host 940 transmits and receives grayscale data, captures an image using the camera module 910, and displays an image on the liquid crystal panel 512 based on operational information from an operation input section 970.

The invention is not limited to the above-described embodiments. Various modifications and variations may be made within the spirit and scope of the invention. For example, the invention may be applied not only to drive the above-described liquid crystal display panel, but also to drive an electroluminescent or plasma display device.

The above embodiment illustrates an example in which the invention is applied to the charge-pump circuit. Note that the above embodiment is not limited to the voltage boost method of the charge-pump circuit and the charge-pump circuit.

Some of the requirements of any claim of the invention may be omitted from a dependent claim which depends on that claim. Some of the requirements of any independent claim of the invention may be allowed to depend on any other independent claim.

Although only some embodiments of the invention are described in detail above, those skilled in the art would readily appreciate that many modifications are possible in the embodiments without materially departing from the novel teachings and advantages of the invention. Accordingly, such modifications are intended to be included within the scope of the invention.

What is claimed is:

1. A semiconductor device comprising:
first and second signal lines through which signals with the same phase and the same amplitude are transmitted; and
third and fourth signal lines through which signals with different phases or different amplitudes are transmitted;
a line-to-line distance when the first and second signal lines are disposed in parallel being shorter than a line-to-line distance when the third and fourth signal lines are disposed in parallel.

2. A semiconductor device comprising:
first and second signal lines through which signals with the same phase and the same amplitude are transmitted; and
third and fourth signal lines through which signals with different phases or different amplitudes are transmitted;
the first and second signal lines being adjacently disposed in parallel; and
the third and fourth signal lines being disposed in parallel with at least one signal line provided between the third and fourth signal lines.

3. The semiconductor device as defined in claim 1,
wherein the signals transmitted through the first and second signal lines differ in voltage level.

4. The semiconductor device as defined in claim 2,
wherein the signals transmitted through the first and second signal lines differ in voltage level.

5. The semiconductor device as defined in claim 1,
wherein the signals transmitted through the third and fourth signal lines differ in voltage level.

6. The semiconductor device as defined in claim 2,
wherein the signals transmitted through the third and fourth signal lines differ in voltage level.

7. The semiconductor device as defined in claim 1, comprising:
a plurality of connection terminals each of which is connected with one end of a flying capacitor; and
a plurality of switch elements switch-controlled according to a charge-pump operation using the flying capacitors connected with the connection terminals;
wherein the first to fourth signal lines are signal lines each of which electrically connects a connection node of the switch elements with the connection terminal.

8. The semiconductor device as defined in claim 2, comprising:
a plurality of connection terminals each of which is connected with one end of a flying capacitor; and
a plurality of switch elements switch-controlled according to a charge-pump operation using the flying capacitors connected with the connection terminals;
wherein the first to fourth signal lines are signal lines each of which electrically connects a connection node of the switch elements with the connection terminal.

9. The semiconductor device as defined in claim 7,
wherein voltages of the first and second signal lines are supplied to both ends of one flying capacitor.

10. The semiconductor device as defined in claim 8,
wherein voltages of the first and second signal lines are supplied to both ends of one flying capacitor.

11. The semiconductor device as defined in claim 7,
wherein the first and second signal lines are adjacently disposed in a direction perpendicular to a wiring arrangement plane of the semiconductor device in which the first to fourth signal lines are disposed.

12. The semiconductor device as defined in claim 8,
wherein the first and second signal lines are adjacently disposed in a direction perpendicular to a wiring arrangement plane of the semiconductor device in which the first to fourth signal lines are disposed.

13. The semiconductor device as defined in claim 7, comprising:
a driver section which drives an electro-optical device based on a voltage of the connection node which outputs a voltage increased by the charge-pump operation among one or more connection nodes of the switch elements.

14. The semiconductor device as defined in claim 8, comprising:
a driver section which drives an electro-optical device based on a voltage of the connection node which outputs a voltage increased by the charge-pump operation among one or more connection nodes of the switch elements.

15. An electro-optical device comprising:
a plurality of scan lines;
a plurality of data lines;
a plurality of pixels;
a scan line driver circuit which scans the scan lines; and
the semiconductor device as defined in claim 13 which drives the data lines.

16. An electro-optical device comprising:
a plurality of scan lines;
a plurality of data lines;
a plurality of pixels;
a scan line driver circuit which scans the scan lines; and
the semiconductor device as defined in claim 14 which drives the data lines.

17. An electronic instrument comprising the electro-optical device as defined in claim 15.

18. An electronic instrument comprising the electro-optical device as defined in claim 16.
